(19) United States
(12) Patent Application Publication
(10) Pub. No.: US 2025/0118594 A1
(43) Pub. Date: Apr. 10, 2025

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Chia-Wei SU, Hsinchu (TW); Hsin-Ping CHEN, Hsinchu (TW); Yung-Hsu WU, Hsinchu (TW); Li-Ling SU, Hsinchu (TW); Chan-Yu LIAO, Hsinchu (TW); Shao-Kuan LEE, Hsinchu (TW); Ting-Ya LO, Hsinchu (TW); Hsin-Yen HUANG, Hsinchu (TW); Hsiao-Kang CHANG, Hsinchu (TW)

(73) Assignee: Taiwan Semiconductor Manufacturing Company, Ltd., Hsinchu (TW)

(21) Appl. No.: 18/377,513

(22) Filed: Oct. 6, 2023

(51) Int. Cl. H01L 21/768; H01L 23/522; H01L 23/528; H01L 23/532

(52) U.S. Cl. CPC H01L 21/76816; H01L 21/76832; H01L 21/76834; H01L 23/5226; H01L 23/5283; H01L 23/53295

(57) ABSTRACT

The semiconductor structure and a manufacturing method thereof are provided. The semiconductor structure includes a first dielectric layer, a first metal layer, a second metal layer, a first etching stop layer, a second etching stop layer, a second dielectric layer, a first via and a second via. The first metal layer and the second metal are embedded in the first dielectric layer. The first etching stop layer is disposed on the first dielectric layer. The second etching stop layer is disposed on the first etching stop layer. The second dielectric layer is disposed on the second etching stop layer. The first via and the second via are embedded in the second dielectric layer. A width of the second etching stop layer is smaller a width of the first etching stop layer.

### BACKGROUND

The disclosure relates in general to a semiconductor structure having a via landing on a meal layer and a manufacturing method thereof, and more particularly to a semiconductor structure and a manufacturing method thereof.

For advanced node, some vias will land on same metal layers to reduce parasitic capacitance. However, this design will cause restricted via size due to the time dependent dielectric breakdown (TDDB) window.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows a semiconductor structure according to one embodiment.

FIG. 2 shows a landing offset on the semiconductor structure according to one embodiment.

FIGS. 3 to 8 illustrate a manufacturing method of the semiconductor structure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

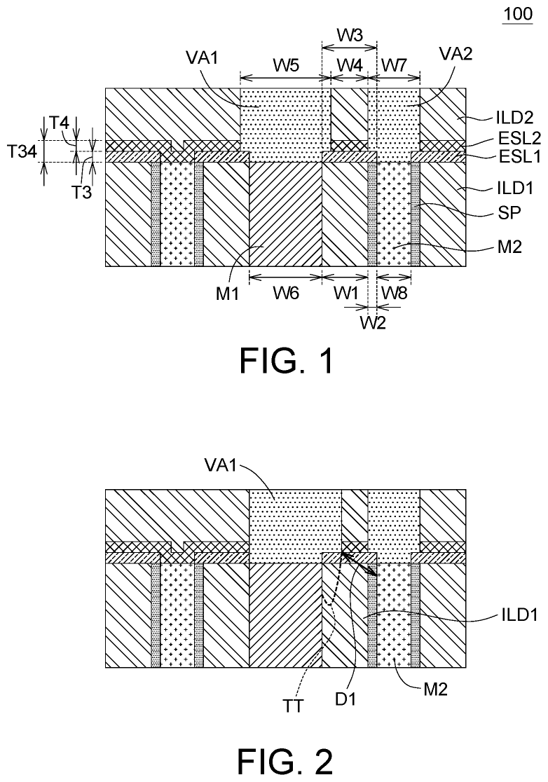

Please refer to FIG. 1, which shows a semiconductor structure 100 according to one embodiment. The semiconductor structure 100 includes a first dielectric layer ILD1, a first metal layer M1, a second metal layer M2, a spacer SP1, a first etching stop layer ESL1, a second etching stop layer ESL2, a second dielectric layer ILD2, a first via VA1, and a second via VA2.

The first dielectric layer ILD1 is, for example, an interlayer dielectric (ILD) layer. The material of the first dielectric layer ILD1 is, for example, silicon oxide (SiO), silicon oxycarbide (SiCO), silicon carbon nitride (SiCN), silicon oxycarbonitride (SiCON), silicon oxynitride (SiNO), the like or a combination thereof.

The first metal layer M1 is embedded in the first dielectric layer ILD1. The first metal layer M1 is, for example, a metal-to-drain contact, usually called “MD.” In the example of the FIG. 1, the first dielectric layer ILD1 exposes the top of the first metal layer M1. The material of the first metal layer M1 is, for example, tungsten (W), ruthenium (Ru), cobalt (Co), copper (Cu), aluminum (Al), nickel (Ni), gold (Au), silver (Ag), gold-aluminum (Au—Al), molybdenum (Mo), the like, or a combination thereof.

The second metal layer M2 is embedded in the first dielectric layer ILD1 and separated from the first metal layer M1. In the example of the FIG. 1, the first dielectric layer ILD1 exposes the top of the second metal layer M2. The second metal layer M2 is, for example, a metal gate, usually called “MG.” The material of the second metal layer M2 is, for example, tungsten (W), ruthenium (Ru), cobalt (Co), copper (Cu), aluminum (Al), nickel (Ni), gold (Au), silver (Ag), gold-aluminum (Au—Al), molybdenum (Mo), the like, or a combination thereof. The material of the first metal layer M1 and the material of the second metal layer M2 could be the same or different.

The spacer SP is disposed at the lateral wall of the second metal layer M2. The spacer SP is disposed between the second metal layer M2 and the first dielectric layer ILD1. The material of the spacer SP is, for example, a nitrogen-containing dielectric material, a carbon-containing dielectric material or both, and the spacer SP has a dielectric constant less than about 10, or even less than about 5. In some embodiments, the spacer SP includes silicon nitride (SiN), silicon carbon nitride (SiCN), silicon oxycarbonitride (SiCON), SiOR (wherein R is an alkyl group such as CH3, C2H5 or C3H7), silicon carbon (SiC), silicon oxycarbide (SiCO), silicon oxynitride (SiNO), the like, or a combination thereof.

The first etching stop layer ESL1 is disposed on the first dielectric layer ILD1. As shown in the FIG. 1, the first etching stop layer ESL1 fully covers the first dielectric layer ILD1 and the spacer SP. The width W3 of the first etching stop layer ESL1 is substantially equal to the sum of the width W1 of the first dielectric layer ILD1 and the width W2 of the spacer SP.

The first etching stop layer ESL1 does not cover the first metal layer M1 and the second metal layer M2. In this embodiment, the first etching stop layer ESL1 does not cover any metal layer. The thickness T3 of the first etching stop layer ESL1 is, for example, 1 nm to 100 nm. The material of the first etching stop layer ESL1 is, for example, Aluminum (Al), Zirconium (Zr), Yttrium (Y), Hafnium (Hf), Zinc (Zn), Silicon (Si) or the nitride/oxide/carbide composition thereof.

The second etching stop layer ESL2 is disposed on the first etching stop layer ESL1. The second etching stop layer ESL2 does not cover whole of the first etching stop layer ESL1. The second etching stop layer ESL2 exposes the two edges of the first etching stop layer ESL1. As shown in the FIG. 1, the width W4 of the second etching stop layer ESL2 is smaller than the width W3 of the first etching stop layer ESL1. A thickness T4 of the second etching stop layer ESL2 is 1 nm to 100 nm. A thickness T34 of a combination of the first etching stop layer ESL1 and the second etching stop layer ESL2 is 1 nm to 200 nm. The material of the second etching stop layer ESL2 is, for example, silicon oxide (SiO), silicon oxycarbide (SiCO), silicon carbon nitride (SiCN), silicon oxycarbonitride (SiCON), silicon oxynitride (SiNO), silicon nitride (SiN), the like or a combination thereof. The dielectric constant of the second etching stop layer ESL2 is, for example, about 4 to about 7. The material of the second etching stop layer ESL2 and the material of the first etching stop layer ESL1 are different. For example, the first etching stop layer ESL1 has superior etching stop capability, and the second etching stop layer ESL2 has inferior etching stop capability.

The second dielectric layer ILD2 is disposed on the second etching stop layer ESL2. The material of the second dielectric layer ILD2 is, for example, silicon oxide (SiO), silicon oxycarbide (SiCO), silicon carbon nitride (SiCN), silicon oxycarbonitride (SiCON), silicon oxynitride (SiNO), the like or a combination thereof. The dielectric constant of the second dielectric layer ILD2 is, for example, about 2.5 to about 3.5. The material of the first dielectric layer ILD1 and the material of the second dielectric layer ILD2 may be the same or different.

The first via VA1 is embedded in the second dielectric layer ILD2, and electrically connected to the first metal layer M1. The first via VA1 is for example, a via-to-drain, usually called “VD.” The first via VA1 covers part of the first etching stop layer ESL1. For example, the first via VA1 covers the two edges of the first etching stop layer ESL1. The width W5 of the first via VA1 is larger than the width W6 of the first metal layer M1. The material of the first via VA1 is, for example, tungsten (W), ruthenium (Ru), cobalt (Co), copper (Cu), aluminum (Al), nickel (Ni), gold (Au), silver (Ag), gold-aluminum (Au—Al), molybdenum (Mo), the like, or a combination thereof.

The second via VA2 is embedded in the second dielectric layer ILD2, separated from the first via VA1 and electrically connected to the second metal layer M2. The second via VA2 is for example, a via-to-gate, usually called “VG.” The second via VA2 covers part of the first etching stop layer ESL1. For example, the second via VA2 covers the two edges of the first etching stop layer ESL1. The width W7 of the second via VA2 is larger than the width W8 of the second metal layer M2. The second etching stop layer ESL2 is disposed between the first via VA1 and the second via VA2. The material of the second via VA2 is, for example, tungsten (W), ruthenium (Ru), cobalt (Co), copper (Cu), aluminum (Al), nickel (Ni), gold (Au), silver (Ag), gold-aluminum (Au—Al), molybdenum (Mo), the like, or a combination thereof. The material of the first via VA1 and the material of the second via VA2 could be the same or different.

The first via VA1 and the second via VA2 are at the same level to reduce the gate-drain parasitic capacitance (Cgd). However, this design would restrict the size of the first via VA1 or the second via VA2 due to the process window on the first via VA1 and the second metal layer M2, and the process window on the second via VA2 and the first metal layer M1.

In this embodiment, the first etching stop layer ESL1 has superior etching stop capability, and the second etching stop layer ESL2 has inferior etching stop capability. As such, the first etching stop layer ESL1 could well prevent the first dielectric layer ILD1 being etched when patterning the first via VA1 or patterning the second via VA2.

Please refer to FIG. 2, which shows a landing offset on the semiconductor structure 100 according to one embodiment. As shown in the FIG. 2, the first via VA1 is not landed at a correct location. Because the first etching stop layer ESL1 has superior etching stop capability, the first via VA1 is blocked by the first etching stop layer ESL1. The first via VA1 does not extend down into the first dielectric layer ILD1. A large distance D1 between the first via VA1 and the second metal layer M2 is kept. As such, any tiger tooth TT (as shown by the dotted line in the FIG. 2) would not be happened and the time dependent dielectric breakdown (TDDB) window could be improved.

In this embodiment, to enlarge size of the first via VA1/the second via VA2 (VD/VG) for low Rc requirement, this embodiment proposes a new scheme of the first via VA1/the second via VA2 (VD/VG). By virtue of high-selectivity depositing the first etching stop layer ESL1 and the second etching stop layer ESL2 with high etching-selectivity to the first etching stop layer ESL1, the semiconductor structure 100 could have a beneficial profile for the first via VA1/the second via VA2 (VD/VG), larger top critical dimension (CD) and small bottom critical dimension (CD).

In addition, because the first etching stop layer ESL1 and the second etching stop layer ESL2 are thinner and have low dielectric constant (low-k), and the second dielectric layer ILD2 has low dielectric constant (low-k), the parasitic capacitance of the first via VA1/the second via VA2 (VD/VG) in the middle end-of-line (MEOL) could be reduced.

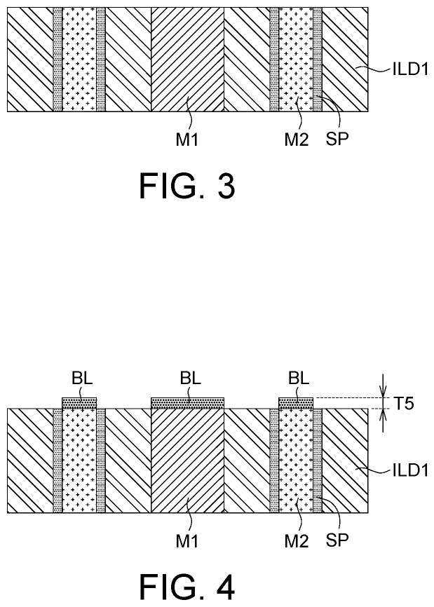

Please refer to FIGS. 3 to 8, which illustrate a manufacturing method of the semiconductor structure 100. As shown in the FIG. 3, the first dielectric layer ILD1, the first metal layer M1, the second metal layer M2 and the spacer SP are formed. The first metal layer M1 and the second metal layer M2 are embedded in the first dielectric layer ILD1 and are separated from each other. As shown in FIG. 3, the top of the first metal layer M1 and the top of the second metal layer M2 are located at the same height. In another embodiment, the top of the second metal layer M2 may be lower than the top of the first metal layer M1.

The first dielectric layer ILD1 could be formed, for example, by spin coating, Plasma Enhanced Chemical Vapor Deposition (PECVD), Plasma Enhanced Atomic Layer Deposition (PEALD) or other suitable process. The first metal layer M1 and the second metal layer M2 could be formed, for example, by Electro Chemical Plating (ECP), Electroless Deposition (ELD), Chemical Vapor Deposition (CVD), Physical Vapor Deposition (PVD), plating or other suitable processes.

Then, in the FIG. 4, a blocking layer BL is formed on the first metal layer M1 and the second metal layer M2. In this step, the first metal layer M1 and the second metal layer M2 are pre-cleaned to remove some particles and oxides on the first metal layer M1 and the second metal layer M2. Next, a polymer inhibitor is formed the first dielectric layer ILD1, the first metal layer M1 and the second metal layer M2. The polymer inhibitor could be attached to the metal material well, but could not be attached to the non-metal material. Therefore, the polymer inhibitor only stays on the first metal layer M1 and the second metal layer M2. Then, the polymer inhibitor is cured at 10° C. to 450° C. to from the blocking layer BL on the first metal layer M1 and the second metal layer M2.

Afterwards, as shown in the FIG. 4, the blocking layer BL only covers the first metal layer M1 and the second metal layer M2, and does not cover the first dielectric layer ILD1 and the spacer SP. The first dielectric layer ILD1 and the spacer SP are exposed by the blocking layer BL.

The material of the blocking layer BL is, for example, a polymer inhibitor composed of C, O, N, Cl or F, a self-assembly monolayer composed of phosphonic acid material, thiol material or silane-based material, benzotriazole (BTA), thiol (—SH) material, or phosphonic acid (—POOH) material. The thickness T5 of the blocking layer BL is, for example, 1 nm to 5 nm.

The blocking layer BL could be formed, for example, by vapor atomic layer deposition (ALD), monolayer doping (MLD), chemical vapor deposition (CVD), spin coating, dipping, or spray.

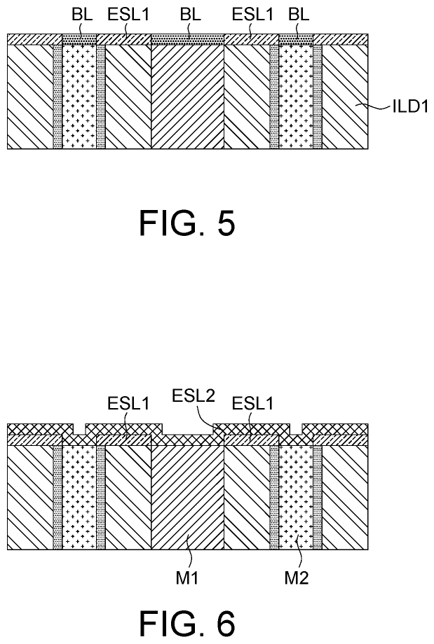

Next, as shown in the FIG. 5, the first etching stop layer ESL1 is selectively deposited on the first dielectric layer ILD1 by using the blocking layer BL as a mask. In this step, the first etching stop layer ESL1 is formed by, for example, chemical vapor deposition (CVD), monolayer doping (MLD), atomic layer deposition (ALD), spin-on, or electro-less plating processes. The first etching stop layer ESL1 is formed, for example, in the spaces among the blocking layer BL. For example, the first etching stop layer ESL1 does not cover the blocking layer BL, so that the blocking layer BL could be removed easily.

Then, as shown in the FIG. 6, the blocking layer BL is removed and the second etching stop layer ESL2 is deposited on the first metal layer M1, the second metal layer M2 and the first etching stop layer ESL1. In this step, the blocking layer BL is removed, for example, by thermal annealing, plasma treatment or wet approach. After the blocking layer BL is removed, the top of the first metal layer M1 and the top of the second metal layer M2 are exposed. The second etching stop layer ESL2 is formed, for example, by chemical vapor deposition (CVD), monolayer doping (MLD), atomic layer deposition (ALD), spin-on, or electro-less plating processes.

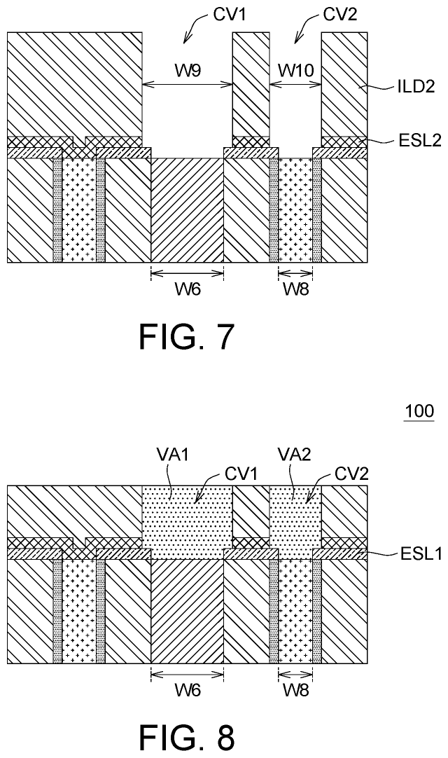

Afterwards, as shown in the FIG. 7, the second dielectric layer ILD2 is formed on the second etching stop layer ESL2. The second dielectric layer ILD2 could be formed, for example, by spin coating, Plasma Enhanced Chemical Vapor Deposition (PECVD), Plasma Enhanced Atomic Layer Deposition (PEALD) or other suitable process.

Next, as shown in the FIG. 7, the second dielectric layer ILD2 is etched to form a first concave CV1 and a second concave CV2. In this step, the second dielectric layer ILD2 could be etched, for example, by wet etching, dry etching or other suitable process. Because the first etching stop layer ESL1 has superior etching stop capability, the width W9 of the first concave CV1 could be larger than the width W6 of the first metal layer M1 without etching the first dielectric layer ILD1. Because the first etching stop layer ESL1 has superior etching stop capability, the width W10 of the second concave CV2 could be larger than the width W8 of the second metal layer M2 without etching the first dielectric layer ILD1. This is to say, the process window is easily controlled in this embodiment.

Next, as shown in the FIG. 8, the first via VA1 and the second via VA2 are formed in the first concave CV1 and the second concave CV2 respectively. In this step, the first via VA1 and the second via VA2 could be formed, for example, by Electro Chemical Plating (ECP), Electroless Deposition (ELD), Chemical Vapor Deposition (CVD), Physical Vapor Deposition (PVD), plating or other suitable processes. Because the first etching stop layer ESL1 superior etching stop capability, any tiger tooth TT (as shown by the dotted line in the FIG. 2) would not be happened and the etching window could be improved with low contact resistance.

According to the manufacturing method of this embodiment, the blocking layer BL is used to high selectivity deposit the first etching stop layer ESL1 with superior etching stop capability, so that there is a beneficial profile for the first via VA1/the second via VA2 (VD/VG) with larger top critical dimension (CD) and small bottom critical dimension.

According to the embodiments described above, because the first etching stop layer ESL1 has superior etching stop capability, the first via VA1 is blocked by the first etching stop layer ESL1. The first via VA1 does not extend down into the first dielectric layer ILD1. As such, any tiger tooth TT (as shown by the dotted line in the FIG. 2) would not be happened and the time dependent dielectric breakdown (TDDB) window could be improved.

By virtue of high-selectivity depositing the first etching stop layer ESL1 and the second etching stop layer ESL2 with high etching-selectivity to the first etching stop layer ESL1, the semiconductor structure 100 could have a beneficial profile for the first via VA1/the second via VA2 (VD/VG), larger top critical dimension (CD) and small bottom critical dimension (CD).

In addition, because the first etching stop layer ESL1 and the second etching stop layer ESL2 are thinner and have low dielectric constant (low-k), and the second dielectric layer ILD2 has low dielectric constant (low-k), the parasitic capacitance of the first via VA1/the second via VA2 (VD/VG) in the middle end-of-line (MEOL) could be reduced.

According to one embodiment, a semiconductor structure is provided. The semiconductor structure includes a first dielectric layer, a first metal layer, a second metal layer, a first etching stop layer, a second etching stop layer, a second dielectric layer, a first via and a second via. The first metal layer is embedded in the first dielectric layer. The second metal layer is embedded in the first dielectric layer and separated from the first metal layer. The first dielectric layer exposes the first metal layer and the second metal layer. The first etching stop layer is disposed on the first dielectric layer. The second etching stop layer is disposed on the first etching stop layer. The second dielectric layer is disposed on the second etching stop layer. The first via is embedded in the second dielectric layer, disposed on the first etching stop layer and electrically connected to the first metal layer. The second via is embedded in the second dielectric layer, disposed on the first etching stop layer, separated from the first via and electrically connected to the second metal layer. A width of the second etching stop layer is smaller a width of the first etching stop layer.

According to an embodiment based on the previous embodiment, the second etching stop layer is disposed between the first via and the second via.

According to an embodiment based on the previous embodiment, a material of the second etching stop layer is different from a material of the second etching stop layer.

According to an embodiment based on the previous embodiment, the first dielectric layer is fully covered by the first etching stop layer.

According to an embodiment based on the previous embodiment, a thickness of the first etching stop layer is 1 nm to 100 nm.

According to an embodiment based on the previous embodiment, a thickness of the second etching stop layer is 1 nm to 100 nm.

According to an embodiment based on the previous embodiment, a thickness of a combination of the first etching stop layer and the second etching stop layer is 1 nm to 200 nm.

According to another embodiment, a manufacturing method of a semiconductor structure is provided. The manufacturing method of the semiconductor structure includes the following steps. A first dielectric layer, a first metal layer and a second metal layer are formed. The first metal layer and the second metal layer are embedded in the first dielectric layer and are separated from each other. A blocking layer is formed on the first metal layer and the second metal layer. A first etching stop layer is selectively deposited on the first dielectric layer by using the blocking layer as a mask. The blocking layer is removed and a second etching stop layer is deposited on the first metal layer, the second metal layer and the first etching stop layer. A second dielectric layer is formed on the second etching stop layer. The second dielectric layer is etched to form a first concave and a second concave. A first via and a second via are formed in the first concave and the second concave respectively.

According to an embodiment based on the previous embodiment, a material of the blocking layer is a polymer inhibitor composed of C, O, N, Cl or F, a self-assembly monolayer composed of phosphonic acid material, thiol material or silane-based material, benzotriazole (BTA), thiol (—SH) material, or phosphonic acid (—POOH) material.

According to an embodiment based on the previous embodiment, in the step of forming the blocking layer, the blocking layer is formed by vapor atomic layer deposition (ALD), monolayer doping (MLD), chemical vapor deposition (CVD), spin coating, dipping, or spray.

According to an embodiment based on the previous embodiment, in the step forming the blocking layer, the first metal layer and the second metal is pre-cleaned.

According to an embodiment based on the previous embodiment, in the step forming the blocking layer, the blocking layer is cured at 10° C. to 450° C.

According to an embodiment based on the previous embodiment, in the step of removing the blocking layer, the blocking layer is removed by thermal annealing, plasma treatment or wet approach.

According to an alternative embodiment, a semiconductor structure is provided. The semiconductor structure includes a first dielectric layer, a first metal layer, a second metal layer, a first etching stop layer, a second etching stop layer, a second dielectric layer, a first via and a second via. The first metal layer is embedded in the first dielectric layer. The second metal layer is embedded in the first dielectric layer and separated from the first metal layer. The first dielectric layer exposes the first metal layer and the second metal layer. The first etching stop layer is disposed on the first dielectric layer. The second etching stop layer is disposed on the first etching stop layer. The second dielectric layer is disposed on the second etching stop layer. The first via is embedded in the second dielectric layer, disposed on the first etching stop layer and electrically connected to the first metal layer. The second via is embedded in the second dielectric layer, disposed on the first etching stop layer, separated from the first via, and electrically connected to the second metal layer. A width of the first via is larger than a width of the first metal layer.

According to an embodiment based on the previous embodiment, a width of the second etching stop layer is smaller a width of the first etching stop layer.

According to an embodiment based on the previous embodiment, a material of the second etching stop layer is different from a material of the second etching stop layer.

According to an embodiment based on the previous embodiment, the first dielectric layer is fully covered by the first etching stop layer.

According to an embodiment based on the previous embodiment, a thickness of the first etching stop layer is 1 nm to 100 nm.

According to an embodiment based on the previous embodiment, a thickness of the second etching stop layer is 1 nm to 100 nm.

According to an embodiment based on the previous embodiment, a thickness of a combination of the first etching stop layer and the second etching stop layer is 1 nm to 200 nm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first dielectric layer;
a first metal layer, embedded in the first dielectric layer;
a second metal layer, embedded in the first dielectric layer and separated from the first metal layer, wherein the first dielectric layer exposes the first metal layer and the second metal layer;
a first etching stop layer, disposed on the first dielectric layer;
a second etching stop layer, disposed on the first etching stop layer;
a second dielectric layer, disposed on the second etching stop layer;
a first via, embedded in the second dielectric layer and electrically connected to the first metal layer; and
a second via, embedded in the second dielectric layer, separated from the first via and electrically connected to the second metal layer, wherein a width of the second etching stop layer is smaller a width of the first etching stop layer.

2. The semiconductor structure according to claim 1, wherein the second etching stop layer is disposed between the first via and the second via.

3. The semiconductor structure according to claim 1, wherein a material of the second etching stop layer is different from a material of the second etching stop layer.

4. The semiconductor structure according to claim 1, wherein the first dielectric layer is fully covered by the first etching stop layer.

5. The semiconductor structure according to claim 1, wherein a thickness of the first etching stop layer is 1 nm to 100 nm.

6. The semiconductor structure according to claim 1, wherein a thickness of the second etching stop layer is 1 nm to 100 nm.

7. The semiconductor structure according to claim 1, wherein a thickness of a combination of the first etching stop layer and the second etching stop layer is 1 nm to 200 nm.

8. A manufacturing method of a semiconductor structure, comprising:
forming a first dielectric layer, a first metal layer and a second metal layer, wherein the first metal layer and the second metal layer are embedded in the first dielectric layer and are separated from each other;
forming a blocking layer on the first metal layer and the second metal layer;
selectively depositing a first etching stop layer on the first dielectric layer by using the blocking layer as a mask;
removing the blocking layer and depositing a second etching stop layer on the first metal layer, the second metal layer and the first etching stop layer;
forming a second dielectric layer on the second etching stop layer;
etching the second dielectric layer to form a first concave and a second concave; and
forming a first via and a second via in the first concave and the second concave respectively.

9. The manufacturing method of the semiconductor structure according to claim 8, wherein a material of the blocking layer is a polymer inhibitor composed of C, O, N, Cl or F, a self-assembly monolayer composed of phosphonic acid material, thiol material or silane-based material, benzotriazole (BTA), thiol (—SH) material, or phosphonic acid (—POOH) material.

10. The manufacturing method of the semiconductor structure according to claim 8, wherein in the step of forming the blocking layer, the blocking layer is formed by vapor atomic layer deposition (ALD), monolayer doping (MLD), chemical vapor deposition (CVD), spin coating, dipping, or spray.

11. The manufacturing method of the semiconductor structure according to claim 8, wherein in the step forming the blocking layer, the first metal layer and the second metal is pre-cleaned.

12. The manufacturing method of the semiconductor structure according to claim 8, wherein in the step forming the blocking layer, the blocking layer is cured at 10° C. to 450° C.

13. The manufacturing method of the semiconductor structure according to claim 8, wherein in the step of removing the blocking layer, the blocking layer is removed by thermal annealing, plasma treatment or wet approach.

14. A semiconductor structure, comprising:
a first dielectric layer;
a first metal layer, embedded in the first dielectric layer;
a second metal layer, embedded in the first dielectric layer and separated from the first metal layer, wherein the first dielectric layer exposes the first metal layer and the second metal layer;
a first etching stop layer, disposed on the first dielectric layer;
a second etching stop layer, disposed on the first etching stop layer;
a second dielectric layer, disposed on the second etching stop layer;
a first via, embedded in the second dielectric layer, and electrically connected to the first metal layer; and
a second via, embedded in the second dielectric layer, separated from the first via and electrically connected to the second metal layer, wherein a width of the first via is larger than a width of the first metal layer.

15. The semiconductor structure according to claim 14, wherein a width of the second etching stop layer is smaller a width of the first etching stop layer.

16. The semiconductor structure according to claim 14, wherein a material of the second etching stop layer is different from a material of the second etching stop layer.

17. The semiconductor structure according to claim 14, wherein the first dielectric layer is fully covered by the first etching stop layer.

18. The semiconductor structure according to claim 14, wherein a thickness of the first etching stop layer is 1 nm to 100 nm.

19. The semiconductor structure according to claim 14, wherein a thickness of the second etching stop layer is 1 nm to 100 nm.

20. The semiconductor structure according to claim 14, wherein a thickness of a combination of the first etching stop layer and the second etching stop layer is 1 nm to 200 nm.
